(19) United States
(12) Patent Application Publication
(10) Pub. No.: US 2009/0127546 A1
(43) Pub. Date: May 21, 2009

(54) ORGANIC LIGHT EMITTING DIODE AND METHOD FOR THE PRODUCTION THEREOF

(75) Inventors: Olaf Rudiger Hild, Radebeul (DE); Michael Eritt, Dresden (DE)

Correspondence Address: BARNES & THORNBURG LLP, 11 SOUTH MERIDIAN, INDIANAPOLIS, IN, 46204, US

(73) Assignee: Fraunhofer-Gesellschaft zur Forderung der angewandten Forschung e.V., Munich (DE)

(21) Appl. No.: 12/271,138

(22) Filed: Nov. 14, 2008

(30) Foreign Application Priority Data
Nov. 19, 2007 (DE) 10 2007 055 137.3

(51) Int. Cl. H01L 51/52; H01L 33/00

(52) U.S. Cl. 257/40; 257/E33.001; 313/504

(57) ABSTRACT

The invention relates to organic light emitting diodes (OLEDs) and to a method for the production thereof. The organic light emitting diodes according to the invention are distinguished in that a substance is integrated in the layer stack, the electrical conductivity of which is reduced by energy input, as a result of which irreversible damage to organic light emitting diodes, as can occur for example with the formation of defects or particles, can be prevented.

### CROSS REFERENCE TO RELATED APPLICATIONS

This application claims priority under the Convention to German patent application DE 10 2007 055 137.3 filed Nov. 19, 2007. The complete disclosure of DE 10 2007 055 137.3 is hereby incorporated herein by reference.

The invention relates to organic light emitting diodes (OLEDs) and to a method for the production thereof. The organic light emitting diodes according to the invention are distinguished in that a substance is integrated in the layer stack, the electrical conductivity of which is reduced by energy input, as a result of which irreversible damage to organic light emitting diodes, as can occur for example with the formation of defects or particles, can be prevented.

Organic light emitting diodes (OLEDs) are used already nowadays in numerous active and passive matrix displays. Mainly separate small active surfaces, so-called pixels, are thereby operated. In order to use OLEDs for illumination purposes or symbols, the production of large homogeneous surfaces, in particular greater than 1 cm², is necessary. Because of defects or variations in thickness in the OLED layer stacks or even due to particles, raised portions in the surface on substrates, e.g. spikes in the case of ITO (indium-tin oxide), migration and/or diffusion of molecules, atoms and clusters, the result can be irreversible damage to the component. One cause thereby is the increased current flow at these defects which leads to heating of the OLED at this site. Due to this heating, the current flow increases further until the result is irreversible damage to the OLED. This damage leads in most cases to a short circuit between anode and cathode with the result that the entire OLED is no longer capable of functioning.

Early detection of these defects has scarcely been possible to date. Only when damage has taken place is the result frequently formation of particularly brightly lit domains, so-called “bright spots”, because of the increased current density and temperature at this site. This susceptibility to faults and in particular the unpredictability of the damage which is also termed “catastrophic failure” in the state of the art (Aziz, H., Popovic, Z. D., Chem. Mater. 2004, 16, 4522-4532) makes the ability of such components to be commercialized an incalculable risk.

Organic light emitting diodes are known from US 2005/0225234 A1, which have a permanently insulating intermediate layer for avoidance of short circuits, said intermediate layer being applied before or after a process interruption. The disadvantage in the method described here is however that the current flow is limited but the original defects are retained. Furthermore, the use of a permanently insulating layer, i.e. a layer with a constant resistance, also leads to an increased resistance in defect-free regions of the OLED, which requires application of a higher voltage during operation of the OLED.

Starting herefrom, it was the object of the present invention to make available organic light emitting diodes which overcome the disadvantages of the state of the art in that effective protection from damage to the component due to defects, particles or other pre-damage is made possible in a manner locally delimited to this region, as a result of which short circuits in the component can be prevented.

This object is achieved by the generic organic light emitting diodes having the characterising features of claim 1 and the method for the production of organic light emitting diodes having the features of claim 23. The further dependent claims reveal advantageous developments. Furthermore, claim 26 mentions a use according to the invention.

According to the invention, organic light emitting diodes are made available which have a substrate, a first and a second electrode and also at least one OLED functional layer which is disposed between the electrodes and contains or comprises at least one organic material. If necessary, the organic light emitting diodes can have at least one further protective layer.

The core of the invention is that the at least one OLED functional layer and/or the at least one protective layer contain or comprise at least one substance, the electrical conductivity of which is at least reduced by energy input. The energy input is thereby effected preferably thermally and/or electrochemically. In the region of pre-damage to the organic light emitting diode in which an increased current flow and, associated therewith, also heating of the OLED occurs, the mentioned substances can therefore be converted or decomposed, as a result of which the electrical conductivity is at least reduced in these regions so that a short circuit can be avoided.

There should be understood by pre-damage to an OLED in the scope of the present invention, both defects, variations in the layer thickness in the OLED layer stacks, particles, raised portions on the surface of substrates, e.g. spikes in the case ITO, and also the migration or diffusion of molecules, atoms and clusters or similar material deficiencies which can cause an increased current flow in the region of the defective site.

In the state of the art, the production of large-area OLEDS has not been possible to date because of the mentioned problems of spontaneous failure of the elements due to the formation of short circuits because of the mentioned defects. By means of the protective layer according to the invention, total failure of the component can now be prevented. The thinner and more sensitive the protective layer, the less is the damage to OLED which cannot be detected in the ideal case with the naked eye.

The present invention hence reveals a possibility for avoiding “catastrophic failures” by the use of at least one substance which is decomposed or converted by energy input. The thereby forming reaction products then lead to a reduced electrical conductivity in the pre-damaged regions.

The at least one substance is thereby able to be converted or decomposed preferably at a temperature up to 600° C., in particular up to 150° C. The at least one substance can preferably be vaporised at a pressure of 10⁻⁶ mbar.

Preferably, the at least one substance can be converted or decomposed endothermally and/or endergonically.

For the substance according to the invention, compounds of the following classes inter alia can be considered:

azides

amino compounds

azo compounds

carbonates

peroxides

nitro compounds

sulphates

sulphonic acids

(metal) carbonyls

The substituents should preferably be sterically demanding in order to avoid diffusion in the layer. In addition, the substituents should preferably be π-electron-rich and conjugated as far as possible in order to ensure as good conductivity as possible. There are included herein for example phenyl, phenoxy, hydroxyphenoxy, aminophenyl, aminodiphenyl, naphthalenes, anthracenes, tetrazenes, pentacenes, perylenes, thiophenes, pyridines, pyrrols, furans and combinations hereof.

Good overlapping of the π systems is advantageous for achieving good conductivity. If necessary, adaptation of the systems with respect to the energy layers HOMO and LUMO can be required, which preferably can be effected by introducing one or more fluorine atoms.

It is likewise preferred that the mentioned substance is a dopant, as is known in the OLED field in the state of the art and has at the same time the property that, during energy input, the electrical conductivity thereof is at least reduced. With respect to dopants of this type, reference is made to the publications DE 103 38 406 A1 and DE 10 2004 010 054 A1, the disclosure content of which in this respect is also the subject of the present invention.

A variant according to the invention provides that the at least one substance is electrically conductive before energy input and the electrical conductivity of the substance is reduced or entirely lost only at the moment of the energy input.

A preferred variant of the organic light emitting diode according to the invention provides that the at least one substance is converted into a gas by the energy input or releases a gas, as a result of which the electrical conductivity of the substance is at least reduced.

By means of this conversion or decomposition, the conductivity is greatly disturbed at the point, the gas development ensures local lifting of the electrode by forming a bubble or a cavity, as a result of which the current flow is interrupted and a short circuit of the OLED is prevented. It is thereby important that the material which is used is decomposed in mass, the decomposition should preferably be endothermal or even endergonic in order to prevent further heating of the component and to delimit the decomposition locally.

As gases to be released, inert gases are preferred here, such as e.g. nitrogen or carbon dioxide. It is likewise preferred to use a plurality of substances, one or more being able to act as initiator or catalyst. Also a thermally activated reaction between various substances is suitable here, just as the inclusion of the adjacent materials of the OLED layers or of the top contact, e.g. by oxidation of the top contact.

Intramolecular reactions of the at least one substance can likewise be effected in that an initially electrically conductive substance is converted thermally into one or more poorly conductive reaction products.

The protective layer is preferably optically transparent for the light emitted by the OLED.

The layer thickness of this protective layer is material- and component-dependent. The layer thickness should be adjusted according to possibility such that the electrode is lifted only very locally and is not thereby torn. The layer thickness is preferably in a range of 0.1 to 100 mm.

A further preferred embodiment provides that the at least one substance is integrated in the OLED functional layer. The at least one substance is thereby preferably disposed at least in regions in the regions between the active surfaces of the functional layer, i.e. between the pixels.

A preferred embodiment provides that the electrodes are deposited in regions and the at least one protective layer, in the regions adjacent to the electrodes, has the at least one substance so that the reduction in electrical conductivity is delimited locally to these regions.

It is further preferred that the first electrode contains or comprises a material which is optically transparent for the light emitted by the OLED (transparent conductive oxide (TCO)), in particular indium-tin oxide (ITO), zinc oxide, zinc-aluminium oxide, PEDOT (polyethylene dioxythiophene) or polyaniline.

According to the invention, a method is likewise made available for the production of organic light emitting diodes, as described previously, in which deposition, at least in regions, of at least the following layers is effected on a substrate:

a first electrode (2),

at least one OLED functional layer (3) which comprises an organic material at least partially,

if necessary at least one protective layer (5) and

a second electrode (4),

the at least one OLED functional layer (3) and/or the at least one protective layer (5) containing or comprising at least one substance, the electrical conductivity of which is at least reduced by energy input.

The deposition is effected preferably now by PVD, CVD, spin-coating, dip-coating, Langmuir-Blodgett, spraying, pressing, SAMs and/or knife-coating. All the deposition techniques mentioned here should be chosen independently of each other for each deposition step so that even wet chemical steps can be combined with evaporation coating processes.

According to the invention, the use of a substance, as described previously, is likewise made available by incorporation in an OLED layer stack in order to prevent short circuits in the OLED in the region of pre-damage, as was defined previously.

The present invention is described in more detail with reference to the subsequent Figures without wishing to restrict the latter to the special embodiment shown here. In the Figures:

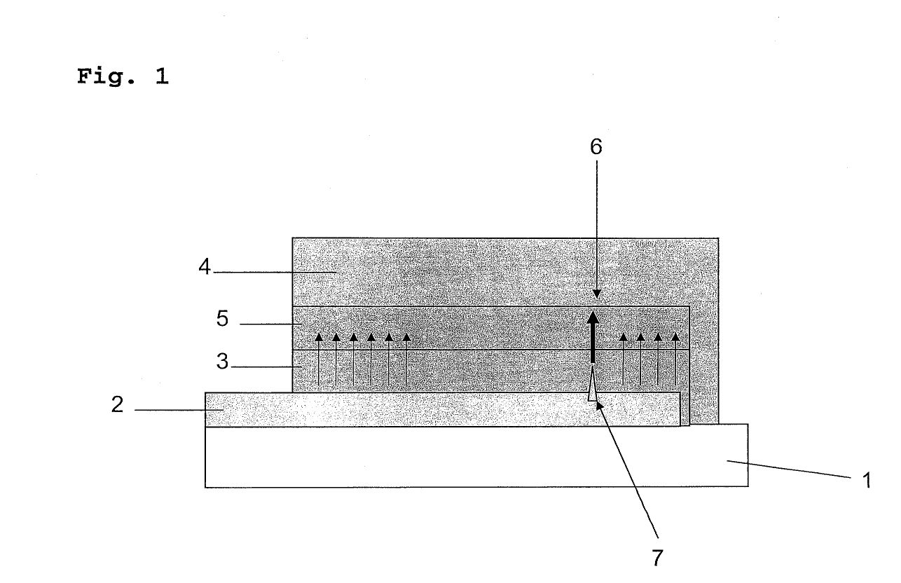

FIG. 1 schematically illustrates an unencapsulated OLED with a protective layer; and,

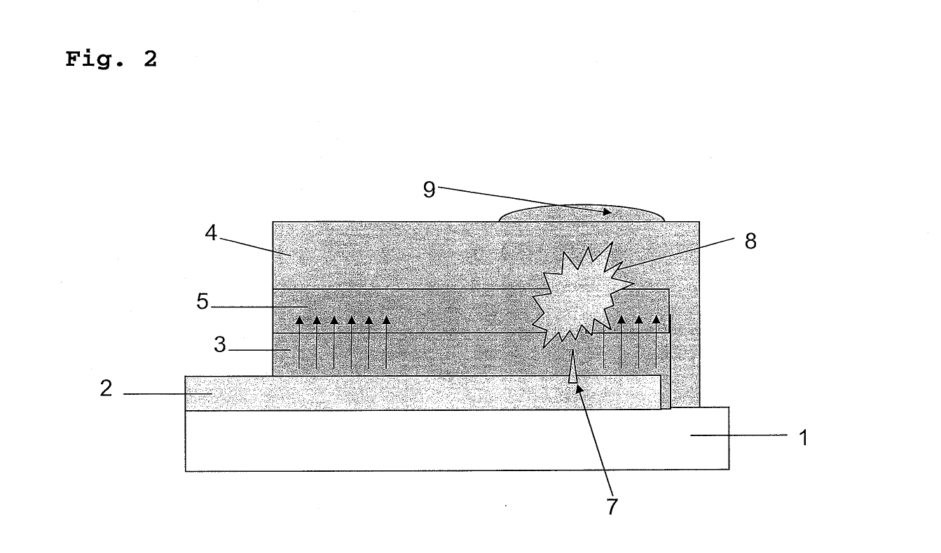

FIG. 2 schematically illustrates locally delimited decomposition of the protective layer of an OLED.

In FIG. 1, an unencapsulated OLED with a protective layer is represented schematically. There is hereby disposed on a substrate 1, a first transparent electrode 2, e.g. made of ITO, an OLED functional layer 3, a protective layer 5 and a second electrode 4. The current or the current density 6 is represented by arrows. The thicker the arrow, the greater the current. At the defect 7 which can be produced for example by means of OLED stack faults (pinholes, clusters, thickness variation, concentration variations with co-evaporated layers or the like), substrate or cover contact faults (layer thickness variation, spikes, clusters), impurities or particles, an increased current flows. As a result, the outcome is heating of the OLEDs. The resistances of the layers which are changed by increasing temperature lead to further heating until ultimately the temperature is so high that the protective layer decomposes.

By means of decomposition, a gaseous component, e.g. nitrogen or carbon dioxide, is formed in the ideal case. The decomposition is delimited locally to the OLED which is heated up to the decomposition temperature of the protective layer and does not damage the remaining OLED. The decomposition 8 is represented schematically in FIG. 2. The expansion accompanying the decomposition leads to the formation of bubbles and local lifting of the metal contact 9.

1-26. (canceled)

27. An organic light emitting diode (OLED) comprising a substrate, a first electrode, a second electrode, at least one OLED functional layer disposed between the first and second electrodes, the at least one OLED functional layer comprising an organic material, and at least one protective layer, at least one of the at least one OLED functional layer and the at least one protective layer comprising at least one substance, the electrical conductivity of the at least one substance being at least reduced by energy input.

28. An organic light emitting diode according to claim 27 wherein the at least one of the at least one OLED functional layer and the at least one protective layer comprises at least one substance, the electrical conductivity of which is at least reduced by at least one of thermal energy input and electrochemical energy input energy input.

29. An organic light emitting diode according to claim 27 wherein the at least one substance comprises a substance that can be at least one of converted and decomposed at a temperature up to 600° C.

30. An organic light emitting diode according to claim 27 wherein the at least one substance comprises a substance that can be vaporized at a pressure of 10 mbar.

31. An organic light emitting diode according to claim 27 wherein the at least one substance comprises a substance that can be at least one of converted at least one of endothermally and endergonically and decomposed at least one of endothermally and endergonically.

32. An organic light emitting diode according to claim 27 wherein the at least one substance is selected from the group consisting of azides, amino compounds, azo compounds, carbonates, peroxides, nitro compounds, sulphates, sulphonic acids, carbonyls, metal carbonyls, and mixtures thereof.

33. An organic light emitting diode according to claim 32 wherein the at least one substance is modified with substituents which are at least one of sterically demanding and contain π-electrons.

34. An organic light emitting diode according to claim 33 wherein the substituents are selected independently of each other from the group consisting of phenyl, phenoxy, hydroxyphenoxy, aminophenyl, aminodiphenyl, naphthalenes, anthracenes, tetrazenes, pentacenes, perylenes, thiophenes, pyridines, pyrrols, furans and combinations thereof.

35. An organic light emitting diode according to claim 27 wherein the at least one substance comprises an electrically conductive substance.

36. An organic light emitting diode according to claim 27 wherein the at least one substance comprises a substance which at least one of is converted into a gas by the energy input, as a result of which the electrical conductivity of the substance is at least reduced, and releases a gas, as a result of which the electrical conductivity of the substance is at least reduced.

37. An organic light emitting diode according to claim 36 wherein the gas effects at least one of a bubble formation, as a result of which the current flow between the first electrode and the second electrode is essentially interrupted, and a cavity formation, as a result of which the current flow between the first electrode and the second electrode is essentially interrupted.

38. An organic light emitting diode according to claim 36 wherein the gas comprises a relatively inert gas.

39. An organic light emitting diode according to claim 27 wherein the substance comprises a first substance which is converted by reaction with at least a second substance, the electrical conductivity of the product of the reaction being reduced relative to the electrical conductivities of the first substance and the at least second substance.

40. An organic light emitting diode according to claim 39 wherein the conversion effects the release of a gas.

41. An organic light emitting diode according to claim 27 wherein the at least one substance is in direct contact with at least one of the first and second electrodes.

42. An organic light emitting diode according to claim 27 wherein the at least one substance is contained in the at least one protective layer, the at least one protective layer disposed between at least one of the first electrode and the OLED functional layer, and the second electrode and the OLED functional layer.

43. An organic light emitting diode according to claim 27 wherein the at least one protective layer and at least one substance comprise a first protective layer including a first substance and a second protective layer including a second substance, the first and second substances being convertible during energy input, the resulting conversion releasing a gas.

44. An organic light emitting diode according to claim 27 wherein the at least one protective layer comprises an optically transparent protective layer transmitting light emitted by the OLED.

45. An organic light emitting diode according to claim 27 wherein the at least one protective layer has a thickness between about 0.1 nm and about 100 nm.

46. An organic light emitting diode according to claim 27 wherein the at least one OLED functional layer comprises the at least one substance, the at least one OLED functional layer comprising at least two active surfaces, the at least one substance being contained at least in regions between the at least two active surfaces of the at least one OLED functional layer.

47. An organic light emitting diode according to claim 27 wherein the first and second electrodes are deposited in regions and regions of the at least one protective layer adjacent to the electrodes contain the at least one substance so that the reduction in electrical conductivity of the at least one protective layer is generally limited to the regions of the at least one protective layer adjacent to the electrodes.

48. An organic light emitting diode according to claim 27 wherein the first electrode comprises a material which is optically transparent for the light emitted by the OLED.

49. An organic light emitting diode according to claim 48 wherein the material is selected from the group consisting of indium-tin oxide (ITO), zinc oxide, zinc-aluminium oxide, polyethylene dioxythiophene (PEDOT) and polyaniline and mixtures of these.

50. A method for the production of organic light emitting diodes (OLEDs), the method comprising depositing at least the following layers in regions on a substrate:
a first electrode,
at least one OLED functional layer which at least partially comprises an organic material, and
a second electrode,
at least one of the at least one OLED functional layer and the at least one protective layer comprising at least one substance, the electrical conductivity of the at least one substance being at least reduced by energy input.

51. The method of claim 50 further comprising depositing at least one protective layer.

52. The method according to claim 50 wherein depositing at least a first electrode, at least one OLED functional layer and a second electrode comprises depositing at least one of the first electrode, the at least one OLED functional layer and the at least one second electrode using a deposition method from the group consisting of PVD, CVD, spin-coating, dip-coating, Langmuir-Blodgett, spraying, pressing, SAMs and knife-coating.

53. The method according to claim 50 further comprising at least one of converting the at least one substance at least one of endothermally and endergonically and decomposing the at least one substance at least one of endothermally and endergonically.

54. A method for the production of organic light emitting diodes (OLEDs), the method comprising depositing at least the following layers in regions on a substrate:
a first electrode,
at least one OLED functional layer which at least partially comprises an organic material, and
a second electrode,
at least one of the at least one OLED functional layer and the at least one protective layer comprising at least one substance, the electrical conductivity of the at least one substance being at least reduced by energy input to prevent short circuits in the OLED in the region of at least one of defects, particles and pre-damage.
